(19) United States
(12) Patent Application Publication
(10) Pub. No.: US 2025/0329599 A1
(43) Pub. Date: Oct. 23, 2025

(54) PACKAGE STRUCTURE AND METHOD OF FORMING THE SAME

(71) Applicant: Taiwan Semiconductor Manufacturing Company, Ltd., Hsinchu (TW)

(72) Inventors: Hsin Ting Lin, Hsinchu County (TW); Kris Lipu Chuang, Hsinchu City (TW); Tsung-Yu Chen, Hsinchu City (TW)

(73) Assignee: Taiwan Semiconductor Manufacturing Company, Ltd., Hsinchu (TW)

(21) Appl. No.: 18/638,713

(22) Filed: Apr. 18, 2024

(51) Int. Cl. H01L 23/36; G02B 6/12; G02B 6/13; H01L 23/00; H01L 25/16

(52) U.S. Cl. CPC H01L 23/36; G02B 6/12007; G02B 6/13; H01L 24/08; H01L 24/16; H01L 24/32; H01L 24/73; H01L 24/80; H01L 24/92; H01L 25/167; G02B 2006/12142; H01L 2224/08145; H01L 2224/16225; H01L 2224/32225; H01L 2224/73204; H01L 2224/80895; H01L 2224/80896; H01L 2224/92125

(57) ABSTRACT

Provided is a package structure and a method of forming the same. The package structure includes: a photonic die having a first surface and a second surface opposite to each other, a buried dielectric layer, a heat sink, and a polymer layer. The photonic die includes a modulator and a heater directly over the modulator. The buried dielectric layer covers the first surface of the photonic die. The heat sink is disposed in the buried dielectric layer to correspond to the modulator. The polymer layer is disposed below the buried dielectric layer, and has an air gap exposing a bottom surface of the heat sink.

### BACKGROUND

Silicon photonics using use silicon waveguides as interconnects to carry optical signals is compatible with the fabrication of integrated circuits (ICs). As compared to data transmission by conductive wires, silicon photonics may offer reduced power consumption, higher efficiency, lower latency, and higher bandwidth. Although existing silicon photonics are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1E illustrate cross-sectional views of intermediate stages in the formation of a package structure in accordance with some embodiments.

FIG. 2 illustrates an enlarged cross-sectional view and a corresponding top view of a region of a package structure of FIG. 1E.

FIG. 3 illustrates a simplified perspective view of a semiconductor layer of FIG. 2.

FIG. 4A and FIG. 4B illustrate top views of a heat sink in accordance with various embodiments.

FIG. 5 illustrate a top view of a thermal insulation layer in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Optical data communication systems operate by modulating laser light to encode digital data patterns. Wavelength division multiplexing (WDM) is widely used to communicate modulated data at different carrier wavelengths on a common optical waveguide. WDM can overcome optical-fiber congestion, which is a potential problem in optical modules that include parallel optical transceivers with one channel per optical fiber. Particularly, by reducing the number of optical fibers per optical module, WDM multiplexing can simplify optical modules, thereby reducing their cost and size.

In dense WDM (DWDM), a narrow spacing between adjacent wavelengths is used. This is typically achieved by modulating data directly onto a highly stable optical carrier and then combining multiple carriers in an optical fiber. DWDM allows a large number of channels to be accommodated within a given wavelength band, and thus offers high performance. In DWDM, a variety of optical devices are used, including modulators, multiplexers (such as add filters), de-multiplexers (such as drop filters), and switches. Ring modulators (including MRMs) are very promising to provide high data rates and ultra-low power and size. A DWDM system using multiple RMs for different channels in an optical transmitter can further scale up the data rate. In order to compensate for fabrication variation, temperature variation, and/or laser wavelength drift, these optical devices are typically phase-tuned to a particular wavelength for a given channel.

Because of process variations and different operating environment, ring modulators usually do not resonate at their target frequencies (or designed frequencies) during operation in an optical system. One way to correct them is to place a heater (such as a metal heater or a silicon heater) adjacent to the ring modulators and use the heater to move the resonance frequency to the target frequency. However, the high temperature provided by the heater may induce the local hot spot in the passivation layer and/or the underfill layer under the heater and/or the ring modulator, thereby resulting in significant reliability issues.

Embodiments of the present disclosure significantly reduce the temperature in the passivation layer and/or the underfill layer under the heater by adding a heat sink in the buried dielectric layer between the heater and the passivation layer for heat dissipation. In addition, a thermal insulation layer (e.g., the air gap) may be formed in the passivation layer to completely physically separate a bottom surface of the heat sink from the passivation layer, so as to further prevent the heat generated from the heater from being transferred into the passivation layer and/or the underfill layer. In this case, the thermal insulation layer is also beneficial for decreasing the required power of the heater, thereby effectively reducing the power consumption.

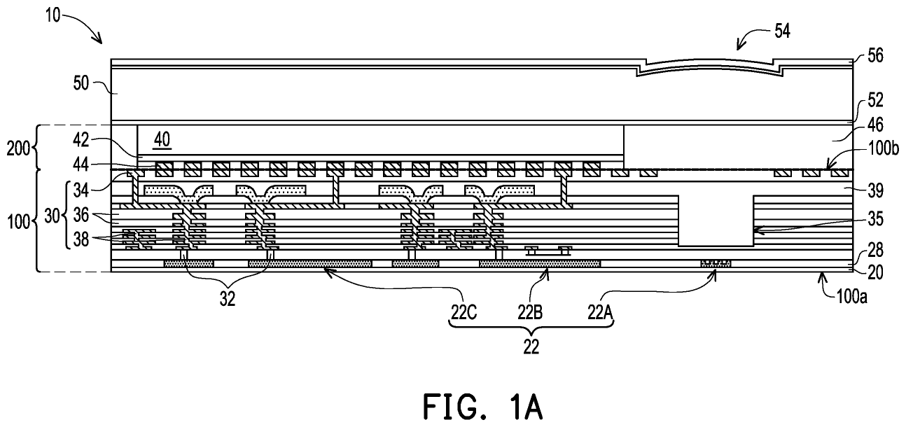

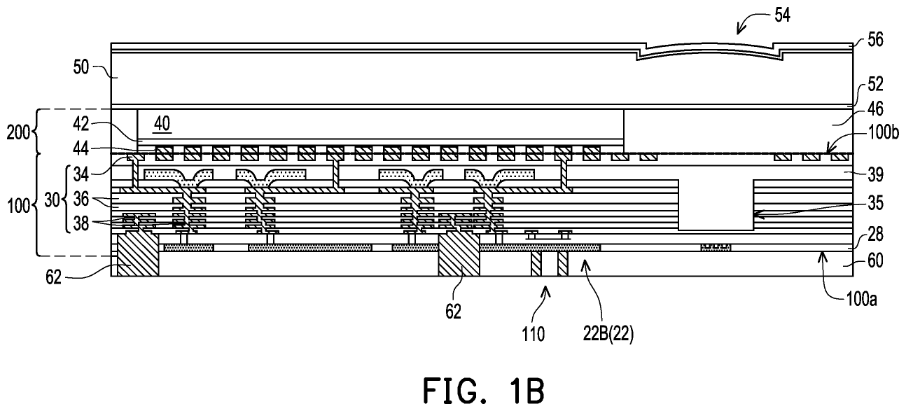

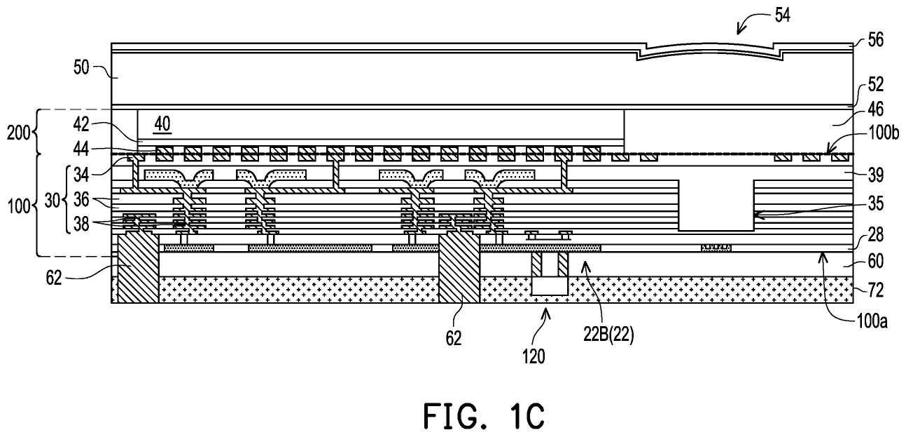

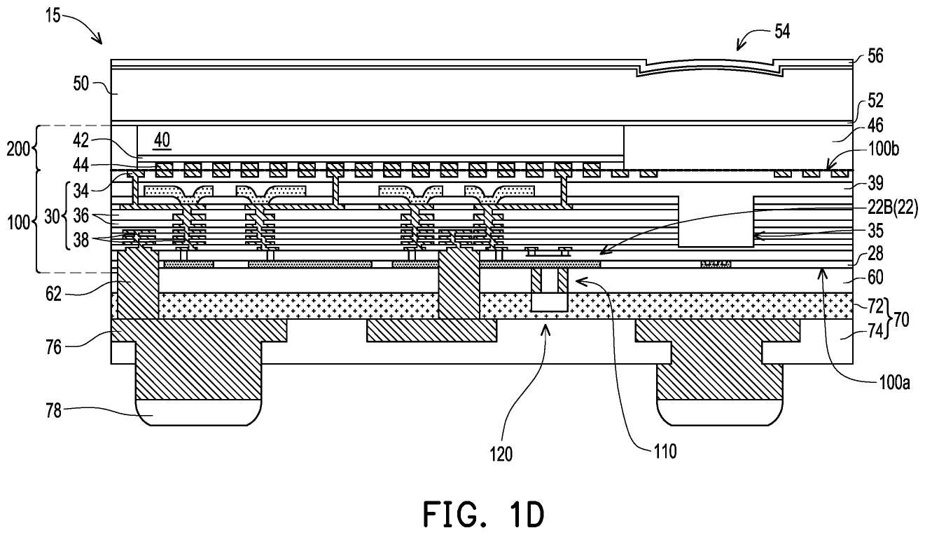

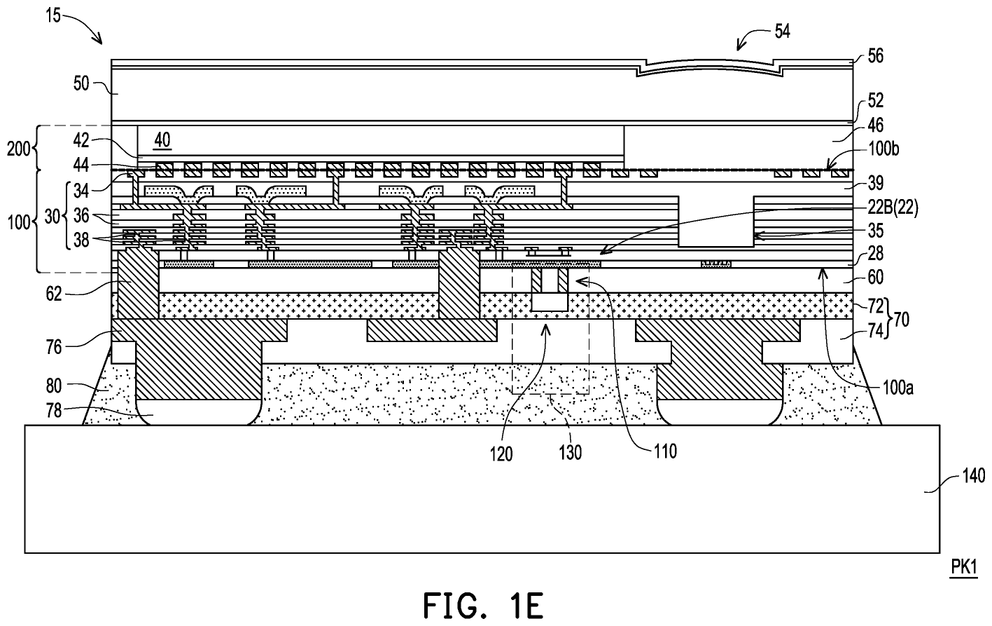

FIG. 1A to FIG. 1E illustrate cross-sectional views of intermediate stages in the formation of a package structure in accordance with some embodiments.

Referring to FIG. 1A, an initial structure 10 is provided. Specifically, the initial structure 10 may include a photonic die 100, an electronic die 200, and a support carrier 50. The method of forming the initial structure 10 may include following steps. First, the photonic die 100 having a first surface 100a and a second surface 100b opposite to each other is provided. The first surface 100a may be referred to as a backside or back surface (e.g., the side facing downwards), and the second surface 100b may be referred to as a frontside or front surface (e.g., the side facing upwards). In some embodiments, the photonic die 100 includes a substrate 20, a semiconductor layer 22, and an interconnect structure 30. The substrate 20 may be a dielectric substrate. For example, the substrate 20 may be formed of or comprise a silicon oxide layer, or may be formed of other dielectric materials (such as silicon oxynitride) that are transparent to light. The semiconductor layer 22 may be formed on the substrate 20. In some embodiments, the semiconductor layer 22 may include an optically transparent material and is configured to permit propagation of an optical signal. In this case, the semiconductor layer 22 may be referred to as an optical transmission structure and/or layer. In the present embodiment, the semiconductor layer 22 may be a silicon (Si) layer. In some alternative embodiments, the semiconductor layer 22 may be a silicon nitride (SiN) layer.

In some embodiments, the semiconductor layer 22 is patterned to form a plurality of photonic devices, which are also referred to as silicon devices. Some examples of the photonic devices include optical devices, which may include a coupler 22A, a modulator 22B, a detector 22C, waveguide, the like, or a combination thereof. It is appreciated that each of the illustrated the coupler 22A, the modulator 22B, and the detector 22C may represent multiple devices. The semiconductor layer 22 may be patterned using suitable photolithography and etching techniques, which may involve etching processes using photoresists to define patterns. Throughout the description, the features that are formed from the semiconductor layer 22 are collectively referred to as a photonic layer and/or an optical transmission structure.

In some embodiments, the coupler 22A is illustrated as an example of a grating coupler having a plurality of trench patterns. In this case, the semiconductor layer 22 may be patterned through one or more etching steps to form the grating coupler having the same or different trench pattern depths. However, the embodiments of the present disclosure are not limited thereto. In some alternative embodiments, the coupler 22A may be an edge coupler. In some embodiments, the modulator 22B may receive electrical signals and modulate optical power within waveguide to generate corresponding optical signals. In addition, the detector 22C may be optically coupled to the waveguide to detect optical signals within the waveguide and generate electrical signals corresponding to the optical signals. In some other embodiments, the semiconductor layer 22 may include other active or passive components, such as laser diodes, optical signal splitters, or other types of photonic structures or devices.

Next, a dielectric layer 28 may be formed on the substrate 20 to cover the semiconductor layer 22. The dielectric layer 28 may be formed of or comprises one or more layers of silicon oxide, silicon nitride, a combination thereof, or the like, and may be formed by chemical vapor deposition (CVD), physical vapor deposition (PVD), atomic layer deposition (ALD), a spin-on-dielectric process, high density plasma chemical vapor deposition (HDP-CVD), flowable CVD (FCVD), or the like, or a combination thereof. The dielectric layer 28 is transparent to light. In some embodiments, the dielectric layer 28 is planarized through a planarization process such as a chemical mechanical polishing (CMP) process or a mechanical grinding process.

After forming the dielectric layer 28, an interconnect structure 30 is formed over the dielectric layer 28. In some embodiments, the interconnect structure 30 includes metallization patterns (e.g., electrically conductive features) formed in one or more dielectric layers. For example, the interconnect structure 30 may include electrically conductive features 38, such as conductive lines and vias formed in a plurality of dielectric layers 36, and conductive pads 34 exposed at the topmost dielectric layer for following bonding. In some embodiments, the dielectric layers 36 comprises a suitable dielectric material, such as silicon oxide, silicon nitride, silicon oxynitride, combinations thereof, multiple layers thereof, or the like, and may be formed using a suitable formation method such as CVD, PVD, lamination, or the like. The dielectric layers 36 may be transparent or opaque to light. The electrically conductive features 38 of the interconnect structure 30 may be formed of an electrically conductive material, such as copper, and may be formed of a suitable formation method such as damascene, dual damascene, plating, or the like.

In some embodiments, the interconnect structure 30 further includes contact plugs 32. The contact plugs 32 may be formed in the bottommost dielectric layer to electrical connect the photonic devices of the semiconductor layer 22, such as the detector 22C or the like. The contact plugs 32 may be formed, for example, by forming openings extending through the bottommost dielectric layer, and filling the openings with conductive materials. The conductive material may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. In some embodiments, the contact plug 32 is electrically connected to the photonic devices of the photonic die 100. The contact plug 32 allows electrical power or electrical signals to be transmitted to the photonic devices of the semiconductor layer 22, and electrical signals to be transmitted from the photonic devices. In this manner, the photonic devices may convert electrical signals into optical signals transmitted by waveguide, and/or may convert optical signals from waveguide into electrical signals.

In FIG. 1A, a portion of the interconnect structure 30 is removed and replaced by a dielectric layer 39. Specifically, a portion of the interconnect structure 30 may be removed through etching to form a recess 35. The removed portion of the interconnect structure 30 may be directly over the coupler 22A. Next, the dielectric layer 39 is deposited, followed by a planarization process to reveal the conductive pads 34.

The material of the dielectric layer 39 is selected to provide more efficient optical coupling between the coupler 22A and a vertically-mounted optical fiber (not shown) and/or micro lens (such as micro lens 54). For example, the dielectric layer 39 may be more transparent, having lower loss, and is less reflective than the dielectric layers 36. In some embodiments, the material of the dielectric layer 39 is similar to that of the dielectric layers 36, but is deposited using a technique that forms the material having a better quality (e.g., less impurities, dislocations, etc.). In this manner, replacing a portion of the dielectric layers 36 of the interconnect structure 30 with the dielectric layer 39 may allow for more efficient operation of the resulting photonic package, and may reduce optical signal loss. For example, the dielectric layer 39 may be formed of or comprise silicon oxide.

In some other embodiments, the dielectric layers 36 are not replaced with the dielectric layer 39. In these embodiments, some regions of the interconnect structure 30 may be substantially free of the conductive features 38 and the conductive pads 34 in order to allow for the transmission of optical signals through the dielectric layers 36. For example, these metal-free regions may extend between the coupler 22A and the micro lens 54, which may be aligned to a vertically-mounted optical fiber to allow optical signals to be coupled between the coupler 22A and the optical fiber.

In a subsequent step, an electronic die 200 is stacked on the photonic die 100. In some embodiments, the electronic die 200 is attached and bonded to the second surface 100b of the photonic die 100 through directly bonding (e.g., hybrid bonding). The electronic die 200 may be, for example, semiconductor devices, dies, or chips that communicate with the photonic devices of the photonic die 100 using electrical signals. One electronic die 200 is shown in FIG. 1A, while the initial structure 10 may also include two or more electronic die 200 in some other embodiments.

The electronic die 200 includes a substrate 40, an interconnect structure 42, and conductive connectors 44, which may be, for example, conductive pads, conductive pillars, or the like. In some embodiments, the substrate 40 may be a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The interconnect structure 42 may include metallization patterns (e.g., electrically conductive features) formed in one or more dielectric layers. The conductive connectors 44 may include conductive pads and/or bonding pads which are exposed at the topmost dielectric layer of the interconnect structure 42.

In some embodiments, the electronic die 200 is directly bonded to the photonic die 100 through hybrid bonding (which includes both of dielectric-to-dielectric bonding and metal-to-metal bonding) to form a die stack structure. Specifically, the conductive pads 34 of the photonic die 100 may be in direct contact with the conductive pads 44 of the electronic die 200, while the topmost dielectric layer of the photonic die 100 may be in direct contact with the bottommost dielectric layer of the electronic die 200, thereby forming a hybrid bonding structure. In some embodiments, the bonding between the electronic die 200 and the photonic die 100 may not include any bump structure, i.e., bumpless. However, in some other embodiments, the bonding between the electronic die 200 and the photonic die 100 may be established through a number of bump structures. For example, the bonding may be hybrid bonding, fusion bonding, direct bonding, dielectric bonding, metal bonding, solder joints (e.g., microbumps), or the like.

In some embodiments of the present disclosure, the electronic die 200 acts as a central processing unit, which includes controlling circuits for controlling the operation of the devices in photonic die 100. In addition, electronic die 200 may include the circuits for processing the electrical signals converted from the optical signals in photonic die 100. In certain embodiments, electronic die 200 may include driver circuitry for controlling optical modulators in the photonics die 100 and gain amplifiers for amplifying the electrical signals received from the photodetectors in photonic die 100. Electronic die 200 may also exchange electrical signals with photonic die 100. The photonic die 100 has the function of receiving optical signals, transmitting the optical signals inside the photonic die 100, transmitting the optical signals out of photonic die 100, and/or communicating electronically with the electronic die 200. In some embodiments, the electronic die 200 may be an electronic integrated circuit (EIC) or the like that provides Serializer/Deserializer (SerDes) functionality. In this manner, the electronic die 200 may act as part of an Input/Output (I/O) interface between optical signals and electrical signals. By the bonding of the electronic die 200 and the photonics die 100, the distance between the electronic die 200 and the photonics die 100 can be effectively shortened to increase the transmission speed of the electrical and/or optical signals, thereby improving performance of the die stack structure. In this case, the bonding of the electronic die 200 and the photonics die 100 is also beneficial to miniaturization of package structure.

After the bonding the electronic die 200 and the photonics die 100, a gap-filling layer 46 is formed on the second surface 100b of the photonics die 100 to laterally encapsulate the electronic die 200. The gap-filling layer 46 may be formed of silicon oxide, silicon nitride, a polymer, the like, or a combination thereof. The gap-filling layer 46 may be formed through CVD, PVD, ALD, a spin-on coating process, HDP-CVD, FCVD, the like, or a combination thereof. The gap-filling layer 46 may include a material (e.g., silicon oxide) that is transparent to light at wavelengths suitable for transmitting optical signals or optical power therein. In some embodiments in which light is not to be projected upwardly through the gap-filling layer 46, the gap-filling layer 46 may comprise a relatively opaque material such as an encapsulant, molding compound, or the like. The gap-filling layer 46 may be planarized using a planarization process such as a CMP process, a grinding process, or the like. In some embodiments, the planarization process may expose the top surface of the electronic die 200. As such, the top surfaces of the electronic die 200 and the gap-filling layer 46 are substantially coplanar.

Next, a support carrier 50 may be attached onto the electronic die 200 and the gap-filling layer 46. In some embodiments, a silicon-containing dielectric layer 52, which may comprise silicon oxide, silicon oxynitride, silicon carbo-nitride, or the like, is used to bond the support carrier 50 to the substrate 40 of the electronic die 200, and to the gap-filling layer 46. The bonding may be performed through fusion bonding, with Si—O—Si bonds formed. There may be a micro lens 54 formed in the support carrier 50. In some embodiments, a protective layer 56 (e.g., polymer layer) may be formed to cover the micro lens 54 and further extend to cover the top surface of the support carrier 50. Alternatively, the protective layer 56 may be omitted. In some embodiments, the support carrier 50 is or comprises a silicon carrier. However, the embodiments of the present disclosure are not limited thereto. In some alternative embodiments, the support carrier 50 may be a glass carrier, a silicon oxide carrier, an organic carrier, or the like.

Referring to FIG. 1B, a buried dielectric layer 60 may be formed on the first surface 100a of the photonic die 100. In some embodiments, the buried dielectric layer 60 may be formed of or comprises one or more layers of silicon oxide, silicon nitride, a combination thereof, or the like, and may be formed by CVD, PVD, ALD, a spin-on-dielectric process, HDP-CVD, FCVD, or the like, or a combination thereof. In some embodiments, the buried dielectric layer 60 and the substrate 20 may have the same dielectric material, such as silicon oxide. In this case, the buried dielectric layer 60 and the substrate 20 can be regarded as the same material layer, and the following figures only refer to this layer with the reference numeral 60. Hereinafter, the first surface 100a of the photonic die 100 may point to the interface between the buried dielectric layer 60 and the dielectric layer 28.

Then, a plurality of through-dielectric vias (TDVs) 62 may be formed in the buried dielectric layer 60. Specifically, the TDVs 62 may be formed for example, by forming openings extending through the buried dielectric layer 60, the dielectric layer 28, and a portion of the dielectric layers 36 of the interconnect structure 30, and filling the openings with conductive materials. The conductive material may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material, so that the bottom surfaces of the TDVs 62 and the buried dielectric layer 60 are substantially coplanar. In some embodiments, the TDVs 62 may be electrically connected to the electrically conductive features 38 of the interconnect structure 30.

In FIG. 1B, a heat sink 110 may be formed in the buried dielectric layer 60 to correspond to the modulator 22B. Specifically, the heat sink 110 is formed directly under the modulator 22B. The detailed structure and configuration of the heat sink 110 will be discussed in subsequent paragraphs (in FIG. 1E and FIG. 2) and will not be detailed here.

In some embodiments, the forming the heat sink 110 further includes forming the TDVs 62. That is, the TDVs 62 and the heat sink 110 may be formed through a parallel formation process. In this case, the TDVs 62 and the heat sink 110 may be formed of the same metallic material and in the same step. However, the embodiments of the present disclosure are not limited thereto. In some alternative embodiments, the TDVs 62 and the heat sink 110 may be formed through a sequential formation process. That is, the TDVs 62 and the heat sink 110 may be formed sequentially.

Referring to FIG. 1C, a first passivation layer 72 may be formed to cover a bottom surface of the buried dielectric layer 60. In some embodiments, the first passivation layer 72 may be formed of or comprises one or more polymer layers, such as polyimide, epoxy resin, acrylic resin, phenol resin, benzocyclobutene (BCB), polybenzoxazole (PBO), or the like, and may be formed by spin coating, lamination, CVD, or the like.

Afterward, a thermal insulation layer 120 may be formed in the first passivation layer 60. In some embodiments, the thermal insulation layer 120 may include an air gap or the like. The detailed structure and configuration of the thermal insulation layer 120 will be discussed in subsequent paragraphs (in FIG. 1E and FIG. 2) and will not be detailed here. In addition, the TDVs 62 may extend into the first passivation layer 72 to reach the bottom surface of the first passivation layer 72.

Referring to FIG. 1D, a second passivation layer 74 and a plurality of conductive pads 76 embedded in the second passivation layer 74 may be formed on the first surface 100a of the photonic die 100. Specifically, the second passivation layer 74 may be formed to cover a bottom surface of the first passivation layer 72. In some embodiments, the second passivation layer 74 may be formed of or comprises one or more polymer layers, such as polyimide, epoxy resin, acrylic resin, phenol resin, BCB, PBO, or the like, and may be formed by spin coating, lamination, CVD, or the like. In some embodiments, the first passivation layer 72 and the second passivation layer 74 may have the same polymer material, such as polyimide. Alternatively, the first passivation layer 72 and the second passivation layer 74 may have different polymer materials. For example, the first passivation layer 72 is a polyimide layer, and the second passivation layer 74 is a PBO layer. Throughout the description, the first passivation layer 72 and the second passivation layer 74 are collectively referred to as a passivation layer 70. In some embodiments, the conductive pads 76 and the electronic die 200 are located on two opposing surfaces of the photonic die 100. Some of the conductive pads 76 may be electrically connected to the TDVs 62. Furthermore, a material of the conductive pads 76 may include a metal material (e.g., copper, aluminum copper, or the like), for example.

After forming the second passivation layer 74 and the conductive pads 76, a plurality of conductive connectors 78 may be formed on the first surface 100a of the photonic die 100 for bonding the photonic die 100 to other components. In some embodiments, the conductive connectors 78 include solder regions, metal pillars, metal pads, metal bumps (sometimes referred to as micro-bumps), or the like. The material of the conductive connectors 78 may include non-solder materials, which may be formed of or comprise copper, nickel, aluminum, gold, multi-layers thereof, alloys thereof, or the like. The conductive connectors 78 may be electrically connected to the electronic die 200 through the conductive pads 76, the TDVs 62, the electrically conductive features 38 of the interconnect structure 30, and the conductive pads 34.

Referring to FIG. 1D and FIG. 1E, an overlying structure 15 of FIG. 1D may be bonded to a circuit substrate 140 through the conductive connectors 78, thereby accomplishing a package structure PK1. In some embodiments, the circuit substrate 140 is made of a semiconductor material, such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the circuit substrate 140 may be a SOI substrate. Generally, an SOI substrate includes a layer of a semiconductor material such as epitaxial silicon, germanium, silicon germanium, SOI, SGOI, or combinations thereof. The circuit substrate 140 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for circuit substrate 140. In the present embodiment, the circuit substrate 140 may be an organic flexible substrate or a printed circuit board, for example.

The circuit substrate 140 may include active and passive devices (not shown), such as transistors, capacitors, resistors, combinations of these, and the like may be used to generate the structural and functional requirements of the design. The circuit substrate 140 may also include metallization layers and vias, and bond pads over the metallization layers and vias. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some other embodiments, the circuit substrate 140 is substantially free of active and passive devices.

In FIG. 1E, an underfill layer 80 may be formed between the first surface 100b of the photonic die 100 and the circuit substrate 140 to encapsulate the conductive connectors 78. In some embodiments, the underfill layer 80 may be formed from any acceptable material, such as a polymer, epoxy, molding underfill, or the like. The underfill layer 80 may be formed by a capillary flow process after the overlying structure 15 is attached or may be formed by a suitable deposition method before the overlying structure 15 is attached. The underfill layer 80 may be a continuous material extending from a bottom surface of the second passivation layer 74 to a top surface of the circuit substrate 140, and may cover a portion of opposite lower sidewalls of the second passivation layer 74.

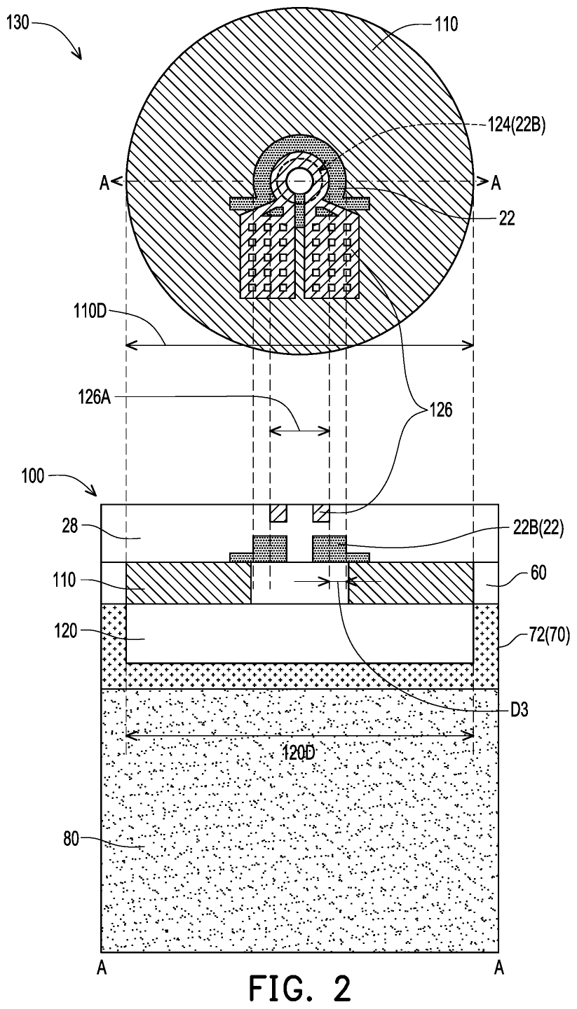

FIG. 2 illustrates an enlarged cross-sectional view and a corresponding top view of a region 130 of the package structure PK1 of FIG. 1E. FIG. 3 illustrates a simplified perspective view of the semiconductor layer 22 of FIG. 2.

Referring to FIG. 2 and FIG. 3, the photonic die 100 may include the semiconductor layer 22, the dielectric layer 28, and a heater 126. As shown in FIG. 1A, the semiconductor layer 22 may include the coupler 22A, the modulator 22B, the detector 22C, or a combination thereof. In some embodiments, the modulator 22B may include a waveguide 122 and a ring modulator 124. The waveguide 122 may extend along a first direction D1. The ring modulator 124 may be arranged along a second direction D2 different from the first direction D1. In some embodiments, the first direction D1 is substantially orthogonal to the second direction D2. The waveguide 122 may be physically separated from the ring modulator 124 in the second direction D2. That is, the waveguide 122 and the ring modulator 124 would not contact to each other.

In some embodiments where a single waveguide 122 is optically coupled to the ring modulator 124, two opposing ends of the waveguide 122 respectively provide the input and output to the ring modulator 124. For example, when the light that meets the resonance condition enters the waveguide 122 at the input end and passes through the ring modulator 124, the light intensity gradually increases due to constructive interference in the ring modulator 124, and then the light outputs at the output end. In this case, the waveguide 122 and the ring modulator 124 may operate as an optical filter, since only light of a specific wavelength may resonate in the ring modulator 124. Herein, the ring modulator 124 may be referred to as a ring waveguide, a ring resonator, or the like. Because of process variations and different operating environment, ring modulators usually do not resonate at their target frequencies (or designed frequencies) during operation in an optical system. Therefore, the heater 126 may be formed directly over the ring modulator 124 to be thermally coupled to the ring modulator 124, thereby moving the resonance frequency to the target frequency. As shown in FIG. 2, the dielectric layer 28 may overlay the ring modulator 124 of the modulator 22B, and the heater 126 may be embedded in the dielectric layer 28 directly over the ring modulator 124. In such embodiment, the heater 126 is physically spaced from the ring modulator 124 through the dielectric layer 28. The spacing between the heater 126 and the ring modulator 124 may vary depending on the optical and product requirements.

In some embodiments, the ring modulator 124 at least partially overlaps the heater 126, so that the heater 126 can heat the ring modulator 124 to a predetermined temperature, thereby moving the resonance frequency to the target frequency. Specifically, the heater 126 may completely overlap the ring modulator 124 in the top view of FIG. 2. That is, the ring modulator 124 has an area within a range of an area 126A of the heater 126. In some embodiments, the heater 126 may include a thermally conductive material such as aluminum, nickel, copper, stainless steel, alloys thereof and/or other suitable materials. The waveguide 122 and the ring modulator 124 may be formed of the same material, such as silicon (Si), silicon nitride (SiN), or the like.

As shown in FIG. 2, the buried dielectric layer 60 may be cover the bottom surface of the semiconductor layer 22 and the bottom surface of the dielectric layer 28. The heat sink 110 may be disposed in the buried dielectric layer 60 to correspond to the ring modulator 124. Specifically, the heat sink 110 may be in (direct) contact with a portion of the bottom surface of the semiconductor layer 22 in the cross-sectional view to dissipate the heat by the ring modulator 124 thermally coupled to the heater 126, thereby avoiding the heat accumulation in the passivation layer 70, or even in the underfill layer 80. In this case, the unnecessary local hot spot will not be formed in the passivation layer 70 and/or the underfill layer 80, so that the temperature of the passivation layer 70 and/or the underfill layer 80 can be effectively decreased, thereby improving the reliability of the package structure PK1. In addition, the heat sink 110 may be laterally offset from the ring modulator 124 to avoid unnecessary electrical coupling. In some embodiments, the heat sink 110 is a ring structure which surrounds the ring modulator 124 in the top view of FIG. 2, and the ring modulator 124 and the heat sink 110 may be spaced by a non-zero distance D3 in the top view to avoid unnecessary electrical coupling. That is, the heat sink 110 may in (direct) contact with the portion of the semiconductor layer 22 other than the ring modulator 124. In such embodiment, the ring modulator 124 and the heat sink 110 are not overlapped with each other in the top view of FIG. 2.

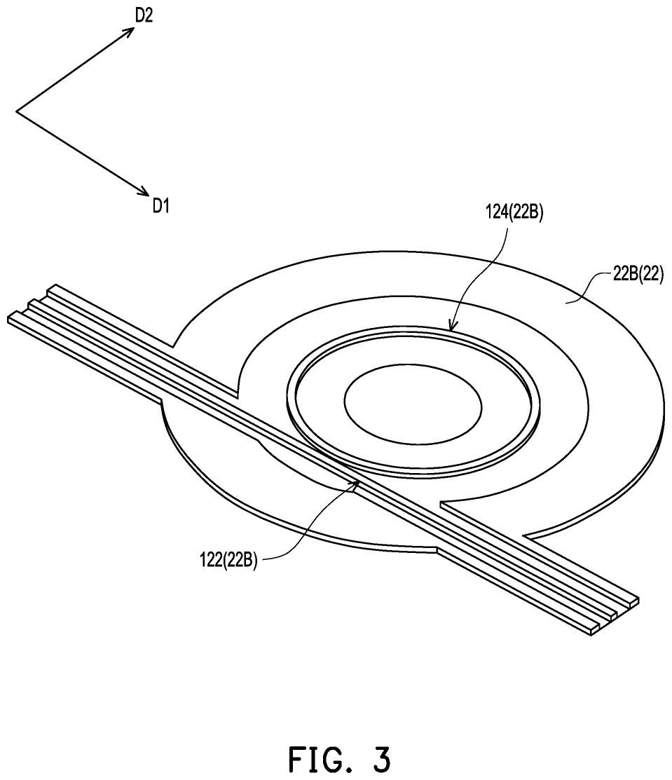

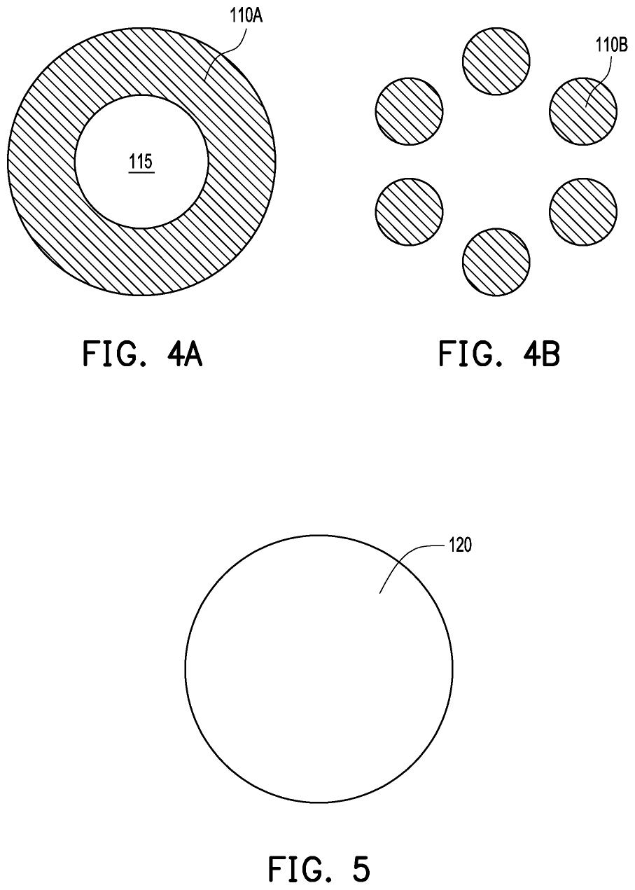

In some embodiments, the heat sink 110 may include a material with a high thermal conductivity, such as copper, silver, gold, aluminum nitride, silicon carbide, diamond, the like, or a combination thereof. For example, the heat sink 110 is a metal layer (i.e., Cu layer) which is electrically floating. The heat sink 110 may have various top-view shapes. As shown in FIG. 4A, the top view shape of the heat sink 110A may be a donut shape, and the inner opening 115 corresponds to the ring modulator 124. That is, the ring modulator 124 is within the range of the inner opening 115 to avoid overlapping of the ring modulator 124 and the heat sink 110A. The size of the ring modulator 124 and the inner opening 115 may vary depending on the optical and product requirements. Although the heat sink 110A illustrated in FIG. 4A is a ring continuous structure, the embodiments of the present disclosure are not limited thereto. In some alternative embodiments, the heat sink may be a ring discontinuous structure. As shown in FIG. 4B, the heat sink 110B may include a plurality of segments arranged in a ring configuration. The segments may or may not be connected to each other. In some embodiments, the segments may include various top-view shapes, such as circles, ovals, rectangles, polygons, the like, or a combination thereof.

Referring back to FIG. 2, the passivation layer 70 is disposed under the buried dielectric layer 60, and the thermal insulation layer 120 is embedded in the passivation layer 70. In some embodiments, the thermal insulation layer 120 is configurated to completely physically separate the bottom surface of the heat sink 110 from the passivation layer 70. Specifically, a top surface of the thermal insulation layer 120 may be in direct contact with the bottom surface of the heat sink 110, and the heat sink 110 has a dimension 110D (e.g., width, area, or diameter) within a range of a dimension 120D (e.g., width, area, or diameter) of the thermal insulation layer 120. In this case, the thermal insulation layer 120 can effectively block the heat generated from the heater 126 from being transferred into the passivation layer 70 and/or the underfill layer 80. On the other hand, the thermal insulation layer 120 is also beneficial for decreasing the required power of the heater 126, thereby effectively reducing the power consumption. Although the dimension 110D of the heat sink 110 illustrated in FIG. 2 is substantially equal to the dimension 120D of the thermal insulation layer 120, the embodiments of the present disclosure are not limited thereto. In some alternative embodiments, the dimension 120D of the thermal insulation layer 120 may greater than the dimension 110D of the heat sink 110.

In some embodiments, the thermal conductivity of the thermal insulation layer 120 is less than the thermal conductivity of the heat sink 110. In this case, the thermal insulation layer 120 can effectively block the heat from the heat sink 110 without being transferred to the surrounding layers, such as the passivation layer 70 and the underfill layer 80. As such, the heat will not be concentrated in the passivation layer 70 and the underfill layer 80 to form unnecessary local hot spots in the passivation layer 70 and the underfill layer 80, thereby improving the reliability of the package structure PK1. In the present embodiment, the thermal insulation layer 120 is an air gap, and the bottom surface of the heat sink 110 is exposed by the air gap. Since the air gap has the thermal conductivity (about 0.026 W/mK) lower than the thermal conductivity of the heat sink 110, the heat can be effectively blocked without being transferred to the passivation layer 70 and the underfill layer 80. Alternatively, the thermal insulation layer 120 may be omitted when the heat sink 110 is enough to solve the local hot spot issue.

Although the top-view shape of the thermal insulation layer 120 (e.g., air gap) illustrated in FIG. 5 is circular, the embodiments of the present disclosure are not limited thereto. In some alternative embodiments, the top-view shape of the thermal insulation layer 120 may include various top-view shapes, such as circles, ovals, rectangles, polygons, the like, or a combination thereof, as long as the thermal insulation layer 120 can completely overlap the heat sink 110 and the ring modulator 124 in the top view. The dimension of the thermal insulation layer 120 may vary depending on the optical and product requirements.

According to some embodiments, a package structure includes a photonic die having a first surface and a second surface opposite to each other, wherein the photonic die comprises a modulator and a heater directly over the modulator; a buried dielectric layer covering the first surface of the photonic die; a heat sink disposed in the buried dielectric layer to correspond to the modulator; and a polymer layer disposed below the buried dielectric layer, and having an air gap exposing a bottom surface of the heat sink.

In some embodiments, the modulator comprises a ring modulator, and the ring modulator at least partially overlaps the heater. In some embodiments, the heat sink is a ring structure which surrounds the ring modulator in a top view, and the ring modulator and the heat sink are not overlapped with each other in the top view. In some embodiments, the heat sink comprises a ring continuous structure or a ring discontinuous structure. In some embodiments, the air gap completely overlaps the heat sink and the ring modulator in the top view. In some embodiments, the heat sink is a metal layer which is electrically floating. In some embodiments, the package structure further includes a circuit substrate bonded to the first surface of the photonic die through a plurality of conductive connectors; an underfill layer disposed between the first surface of the photonic die and the circuit substrate to encapsulate the plurality of conductive connectors; and a plurality of through-dielectric vias (TDVs) penetrate through the buried dielectric layer and the polymer layer to electrically connect the plurality of conductive connectors respectively. In some embodiments, the package structure further includes an electronic die directly bonded to the second surface of the photonic die; a gap-filling layer disposed on the second surface of the photonic die to laterally encapsulate the electronic die; and a support carrier disposed on the electronic die and the gap-filling layer.

According to some embodiments, a method of forming a package structure includes: providing a photonic die having a first surface and a second surface opposite to each other, wherein the photonic die comprises a modulator and a heater directly over the modulator; forming a buried dielectric layer on the first surface of the photonic die; forming a heat sink in the buried dielectric layer to correspond to the modulator; forming a polymer layer to cover a bottom surface of the buried dielectric layer; and forming an air gap in the polymer layer to expose a bottom surface of the heat sink.

In some embodiments, the forming the heat sink in the buried dielectric layer further includes: forming a plurality of through-dielectric vias (TDVs) to penetrate through the buried dielectric layer. In some embodiments, the TDVs and the heat sink are formed of the same metallic material. In some embodiments, the method further includes: bonding a circuit substrate bonded to the first surface of the photonic die through a plurality of conductive connectors; and forming an underfill layer between the first surface of the photonic die and the circuit substrate to encapsulate the plurality of conductive connectors. In some embodiments, the method further includes: directly bonding an electronic die to the second surface of the photonic die; forming a gap-filling layer on the second surface of the photonic die to laterally encapsulate the electronic die; and forming a support carrier on the electronic die and the gap-filling layer.

According to some embodiments, a package structure includes a photonic die having a first surface and a second surface opposite to each other, wherein the photonic die comprises: a semiconductor layer having a ring modulator; a dielectric layer overlying the semiconductor layer; and a heater disposed in the dielectric layer directly over the ring modulator, where the heater is physically spaced from the ring modulator through the dielectric layer; a buried dielectric layer covering a bottom surface of the semiconductor layer and a bottom surface of the dielectric layer; and a heat sink disposed in the buried dielectric layer to contact a portion of the bottom surface of the semiconductor layer and laterally offset from the ring modulator.

In some embodiments, the package structure further includes: a passivation layer disposed below the buried dielectric layer; and a thermal insulation layer disposed in the passivation layer, wherein the heat insulation layer is configurated to completely physically separate a bottom surface of the heat sink from the passivation layer. In some embodiments, a top surface of the thermal insulation layer is in direct contact with the bottom surface of the heat sink, and the heat sink has an area within a range of an area of the thermal insulation layer. In some embodiments, the thermal insulation layer is an air gap, and the bottom surface of the heat sink is exposed by the air gap. In some embodiments, the heater completely overlaps the ring modulator, and the heater is configured to heat the ring modulator to a predetermined temperature. In some embodiments, the heat sink is a ring structure which surrounds the ring modulator in a top view, and the ring modulator and the heat sink are spaced by a non-zero distance in the top view. In some embodiments, the package structure further includes a circuit substrate bonded to the first surface of the photonic die through a plurality of conductive connectors; an underfill layer disposed between the first surface of the photonic die and the circuit substrate to encapsulate the plurality of conductive connectors; a plurality of through-dielectric vias (TDVs) penetrate through the buried dielectric layer and the polymer layer to electrically connect the plurality of conductive connectors respectively; an electronic die directly bonded to the second surface of the photonic die; a gap-filling layer disposed on the second surface of the photonic die to laterally encapsulate the electronic die; and a support carrier disposed on the electronic die and the gap-filling layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a photonic die having a first surface and a second surface opposite to each other, wherein the photonic die comprises a modulator and a heater over the modulator;
a buried dielectric layer covering the first surface of the photonic die;
a heat sink disposed in the buried dielectric layer to correspond to the modulator; and
a polymer layer disposed below the buried dielectric layer, and having an air gap exposing a bottom surface of the heat sink.

2. The package structure of claim 1, wherein the modulator comprises a ring modulator, and the ring modulator at least partially overlaps the heater.

3. The package structure of claim 2, wherein the heat sink is a ring structure which surrounds the ring modulator in a top view, and the ring modulator and the heat sink are not overlapped with each other in the top view.

4. The package structure of claim 3, wherein the heat sink comprises a ring continuous structure or a ring discontinuous structure.

5. The package structure of claim 2, wherein the air gap completely overlaps the heat sink and the ring modulator in the top view.

6. The package structure of claim 1, wherein the heat sink is a metal layer which is electrically floating.

7. The package structure of claim 1, further comprising:
a circuit substrate bonded to the first surface of the photonic die through a plurality of conductive connectors;
an underfill layer disposed between the first surface of the photonic die and the circuit substrate to encapsulate the plurality of conductive connectors; and
a plurality of through-dielectric vias (TDVs) penetrate through the buried dielectric layer and the polymer layer to electrically connect the plurality of conductive connectors respectively.

8. The package structure of claim 1, further comprising:
an electronic die directly bonded to the second surface of the photonic die;
a gap-filling layer disposed on the second surface of the photonic die to laterally encapsulate the electronic die; and
a support carrier disposed on the electronic die and the gap-filling layer.

9. A method of forming a package structure, comprising:
providing a photonic die having a first surface and a second surface opposite to each other, wherein the photonic die comprises a modulator and a heater over the modulator;
forming a buried dielectric layer on the first surface of the photonic die;
forming a heat sink in the buried dielectric layer to correspond to the modulator;
forming a polymer layer to cover a bottom surface of the buried dielectric layer; and
forming an air gap in the polymer layer to expose a bottom surface of the heat sink.

10. The method of claim 9, wherein the forming the heat sink in the buried dielectric layer further comprises:
forming a plurality of through-dielectric vias (TDVs) to penetrate through the buried dielectric layer.

11. The method of claim 10, wherein the TDVs and the heat sink are formed of the same metallic material.

12. The method of claim 9, further comprising:
bonding a circuit substrate bonded to the first surface of the photonic die through a plurality of conductive connectors; and
forming an underfill layer between the first surface of the photonic die and the circuit substrate to encapsulate the plurality of conductive connectors.

13. The method of claim 9, further comprising:
directly bonding an electronic die to the second surface of the photonic die;
forming a gap-filling layer on the second surface of the photonic die to laterally encapsulate the electronic die; and
forming a support carrier on the electronic die and the gap-filling layer.

14. A package structure, comprising:
a photonic die having a first surface and a second surface opposite to each other, wherein the photonic die comprises:
a semiconductor layer having a ring modulator;
a dielectric layer overlying the semiconductor layer; and
a heater disposed in the dielectric layer over the ring modulator, where the heater is physically spaced from the ring modulator through the dielectric layer;
a buried dielectric layer covering a bottom surface of the semiconductor layer and a bottom surface of the dielectric layer; and
a heat sink disposed in the buried dielectric layer to contact a portion of the bottom surface of the semiconductor layer and laterally offset from the ring modulator.

15. The package structure of claim 14, further comprising:
a passivation layer disposed below the buried dielectric layer; and
a thermal insulation layer disposed in the passivation layer, wherein the heat insulation layer is configurated to completely physically separate a bottom surface of the heat sink from the passivation layer.

16. The package structure of claim 15, wherein a top surface of the thermal insulation layer is in direct contact with the bottom surface of the heat sink, and the heat sink has an area within a range of an area of the thermal insulation layer.

17. The package structure of claim 15, wherein the thermal insulation layer is an air gap, and the bottom surface of the heat sink is exposed by the air gap.

18. The package structure of claim 14, wherein the heater completely overlaps the ring modulator, and the heater is configured to heat the ring modulator to a predetermined temperature.

19. The package structure of claim 14, wherein the heat sink is a ring structure which surrounds the ring modulator in a top view, and the ring modulator and the heat sink are spaced by a non-zero distance in the top view.

20. The package structure of claim 14, further comprising:
a circuit substrate bonded to the first surface of the photonic die through a plurality of conductive connectors;
an underfill layer disposed between the first surface of the photonic die and the circuit substrate to encapsulate the plurality of conductive connectors;
a plurality of through-dielectric vias (TDVs) penetrate through the buried dielectric layer and the polymer layer to electrically connect the plurality of conductive connectors respectively;
an electronic die directly bonded to the second surface of the photonic die;
a gap-filling layer disposed on the second surface of the photonic die to laterally encapsulate the electronic die; and
a support carrier disposed on the electronic die and the gap-filling layer.
